(19) United States
(12) Patent Application Publication
(10) Pub. No.: US 2015/0072158 A1
(43) Pub. Date: Mar. 12, 2015

(54) BLACK POLYIMIDE FILM AND PROCESSING METHOD THEREOF

(71) Applicant: TAIMIDE TECHNOLOGY INCORPORATION, Hsinchu County (TW)

(72) Inventors: Chih-Wei LIN, Hsinchu Hsien (TW); Chi-Huan LO, Hsinchu Hsien (TW)

(21) Appl. No.: 14/319,588

(22) Filed: Jun. 30, 2014

(30) Foreign Application Priority Data
Sep. 9, 2013 (TW) 102132480

(51) Int. Cl. C08K 3/04; C08K 3/36; H05K 3/00; H05K 1/05

(52) U.S. Cl. CPC C08K 3/04; H05K 1/056; C08K 3/36; H05K 3/0041
USPC 428/458; 524/606; 216/67

(57) ABSTRACT

A black polyimide film includes a polyimide polymer formed by reaction of diamine monomers with dianhydride monomers, and a carbon black having an oxygen-to-carbon weight ratio higher than 11%. The black polyimide film can prevent flaking of carbon black when it is subject to an etching process, and exhibit desirable characteristics of extension rate and insulation.

### CROSS-REFERENCE TO RELATED APPLICATION(S)

This application claims priority to Taiwan application no. 102132480 filed on Sep. 9, 2013.

### BACKGROUND

1. Field of the Invention

The present invention relates to polyimide films and a processing method thereof.

2. Description of the Related Art

Polyimide film is often used as substrate and coverlay materials in flexible circuit boards (FCB). For these applications, the polyimide film needs to have low gloss to offer a fine texture and appealing appearance, and low transmittance of light and good insulation for protecting the electric circuit carried by the FCB.

In general, desirable gloss, light transmittance, and insulation can be achieved by adding a color pigment (such as pigments, dyes and the like) and a matting agent. For example, a black polyimide film typically contains carbon black to reduce light transmittance and exhibits the desired black color.

In a conventional manufacture process of a flexible circuit board, the polyimide film needs to be treated with laser drill and undergo desmear treatment by plasma etching before taping and electroplating processes. However, as shown in FIGS. 1A-1C, the conventional black polyimide film 1 may be easily subject to decoloration during the plasma etching step 13. The black polyimide film 1 includes a polyimide 11 and carbon particles 12. When etching is applied on the black polyimide film 1, carbon black particles 12 may become exposed and accumulate on the surface of the black polyimide film 1. Flaking of the carbon black particles 12 can be a source of contamination in the processing equipment. Therefore, there is a need for a polyimide film that can reduce decoloration, and address the foregoing issues.

### SUMMARY

The present application describes a black polyimide film that can prevent flaking of carbon black particles, and provide desirable mechanical, insulation and appearance characteristics. In one embodiment, the black polyimide film includes a polyimide polymer formed by reaction of diamine monomers with dianhydride monomers, and a carbon black having an oxygen-to-carbon weight ratio higher than 11%.

In another embodiment, the present application describes a polyimide film that has a low gloss. The polyimide film includes a polyimide polymer formed by reaction of diamine monomers with dianhydride monomers, a carbon black having an oxygen-to-carbon weight ratio higher than 11%, and a matting agent composed of polyimide particles, silicon oxide, or a combination of the polyimide particles and silicon oxide.

The present application also describes a method of processing a black polyimide film, which includes providing a black polyimide film containing a polyimide polymer and a carbon black having an oxygen-to-carbon weight ratio higher than 11%, and etching the black polyimide film, wherein the polyimide polymer and the carbon black are etched with a substantially same etching rate.

### BRIEF DESCRIPTION OF THE DRAWINGS

FIGS. 1A-1C are schematic views illustrating a plasma etching process applied on a conventional black polyimide film; and

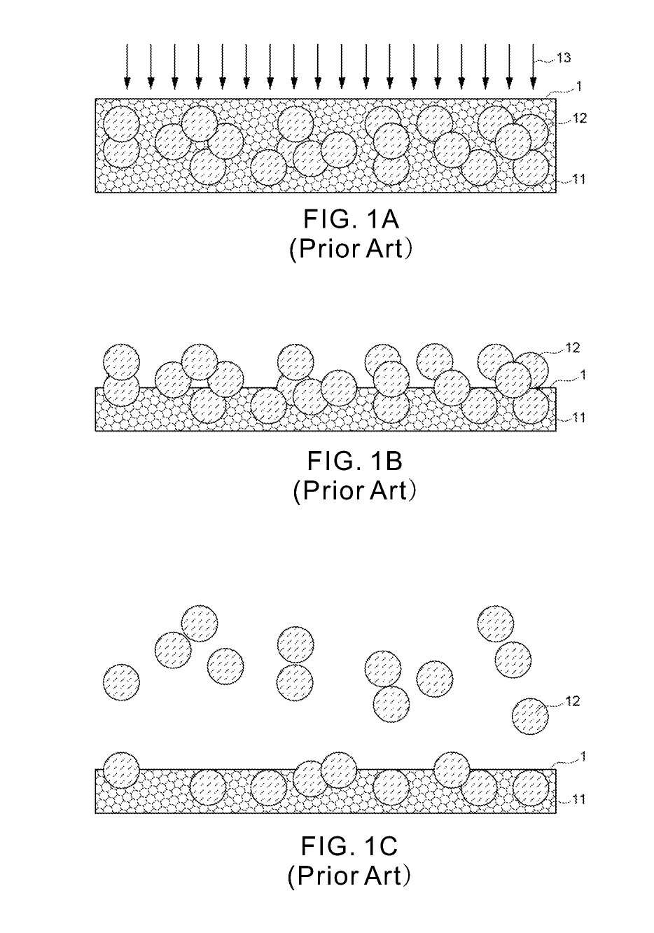

FIGS. 2A and 2B are schematic views illustrating a plasma etching process applied on an embodiment of a black polyimide film.

### DETAILED DESCRIPTION OF THE EMBODIMENTS

The present application describes a black polyimide film containing a polyimide polymer, and a carbon black dispersed in the polyimide polymer. The used carbon black can be in a powder form that has a composition including oxygen, carbon and other chemical elements or compounds. For example, different functional group(s) such as hydroxyl and carboxyl can be present in the surface of the carbon black particles. The carbon black contains atoms of oxygen and carbon, and has an oxygen-to-carbon weight ratio (i.e., total weight of oxygen atoms/total weight of carbon atoms, also referred as “O/C weight ratio” hereinafter) is about 11% or above. In other words, based on the total weight of the carbon atoms, the oxygen atoms occupy 11 wt % or higher in weight. Exemplary embodiments can have the O/C weight ratio of the carbon black at least equal to or higher than 15%, 19%, more preferably 21% or higher, such as 22%, 25%, 30%, 35%, 40%, or any intermediate values between 21% and 40%. According to certain embodiments, more limited ranges of the O/C weight ratio can be between 15% and 40%, between 17% and 30%, or between 19% and 25%.

Based on the total weight of the polyimide film, the weight ratio of the carbon black in the polyimide film can range from 0.5 wt % to 10 wt %, e.g., 0.6 wt %, 0.8 wt %, 1 wt %, 2 wt %, 3 wt %, 4 wt %, 5 wt %, 6 wt %, 7 wt %, 8 wt %, 9 wt %, 9.5 wt %, 9.9 wt %, or any intermediate values between these values. Certain embodiments of the black polyimide film can exemplary have the weight ratio of the carbon black between 2 wt % and 8 wt %.

The polyimide polymer making the film can be obtained by reacting diamine monomers with dianhydride monomers in a substantially equal molar ratio. Examples of the diamine monomers can include oxydianiline (ODA) (e.g., 4,4′-ODA and 3,4′-ODA), phenylenediamine (PDA) (e.g., p-PDA and m-PDA), 2,2′-bis(trifluoromethyl)benzidine (TFMB), and the like. Examples of the dianhydride monomers can include pyromellitic dianhydride (PMDA), biphenyltetracarboxylic dianhydride (BPDA) (e.g., 3,3′,4,4′-BPDA and 2,3′,3,4′-BPDA), benzophenonetetracarboxylic dianhydride (BTDA) (e.g., 3,3′,4,4′-BTDA and 2,3,3′,4″-BTDA), 2,2-bis[4-(3,4-dicarboxyphenoxy) phenyl]propane dianhydride (BPADA), and the like.

In some embodiments, the polyimide film may further include a matting agent. The matting agent can be a polyimide powder, silicon oxide, or a combination thereof.

According to the application's needs, additives can also be incorporated into the polyimide film to confer desired properties to the polyimide film. Examples of the additives can include, without limitation, a processing aid, an antioxidant, a light stabilizer, a flame retardant additive, an anti-static agent, a heat stabilizer, an ultraviolet light absorbing agent and/or a reinforcing agent, which can be used individually or in combination.

Some embodiments of the polyimide film can further contain a black pigment such as cobalt oxide, Fe—Mn—Bi black, Fe—Mn oxide spinel black, (Fe,Mn)₂O₃ black, copper chromite black spinel, lampblack, bone black, bone ash, bone char, hematite, black iron oxide, micaceous iron oxide, black complex inorganic color pigment (CICP), CuCr₂O₄ black, (Ni,Mn,Co)(Cr,Fe)₂O₄ black, aniline black, perylene black, anthraquinone black, chrome green black hematite, iron-chromium mixed oxides and the like, which can be used individually or in combination.

The black polyimide film can be used for preparing a laminate structure, which can include one or multiple metal layer arranged on either one or two opposite surface of the black polyimide film. Examples of the metal can include gold, silver, copper, aluminum, nickel, or an alloy of these metals. Each metal layer can be formed by methods such as physical vapor deposition, chemical vapor deposition, deposition, electroless plating, electroplating and the like.

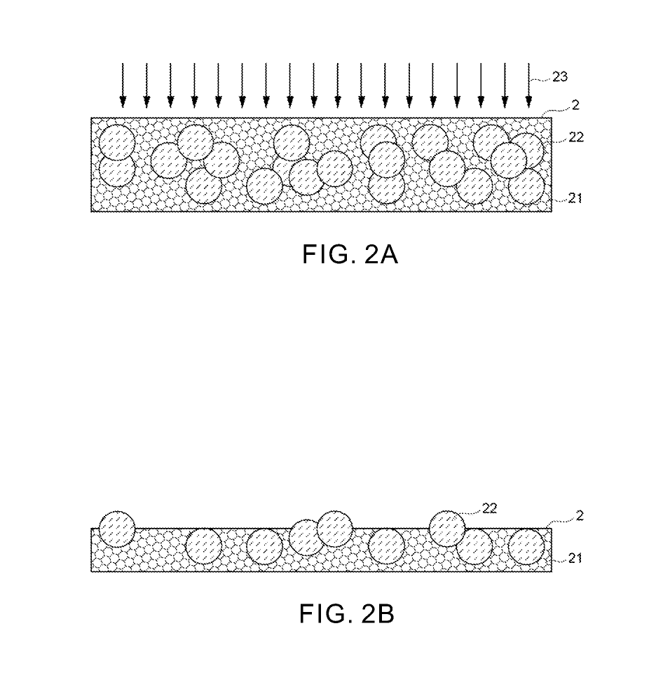

The black polyimide film described herein can effectively retain carbon black particles, and prevent its flaking when the film is subject to a plasma etching process. Referring to FIGS. 2A and 2B, assume that a fabricated black polyimide film 2 contains a polyimide polymer 21 and particles of carbon black 22. A study conducted by the inventors of the present application reveals that the use of carbon black 22 having an O/C weight ratio equal to 11% or higher can substantially reduce the difference of etching rate between the carbon black 22 and the polyimide polymer 21 when plasma etching 23 is applied on the black polyimide film 2. As a result, the etching rate of the carbon black 22 can be substantially equal to that of the polyimide polymer 21, and residual accumulation of the carbon black 22 on the film surface can be significantly reduced or even eliminated. Accordingly, flaking of the carbon black 22 and decoloration of the film 2 can be prevented. These same advantages and benefits can be obtained when the polyimide polymer 21 is derived from different combinations of diamine and dianhydride monomers.

Examples for fabricating the colored polyimide film are described hereinafter in more details.

### EXAMPLES

### Example 1

### Preparation of the Carbon Black Slurry

About 100 g of carbon black (sold by Degussa Company under the catalog designation No. SB6) and about 700 g of DMAC are mixed and agitated for about 60 minutes. The mixture then is processed through a grinder to obtain a carbon black slurry.

Preparation of the Black Polyimide Film

About 4 g of the carbon black slurry is mixed with about 106.6 g of a polyaminc acid (PAA) solution containing about 14.3 wt % of solid content copolymerized by 4,4′-ODA and PMDA at a molar ratio 1:1, and the mixture is agitated homogeneously to obtain a black PAA solution. The black PAA solution is coated on a glass plate support and baked in an oven. The baking condition is set at a temperature of 80° C. for 30 minutes to remove the solvent, and then between 170° C. and 370° C. for 4 hours to form a black polyimide film. The obtained film can contain about 4 wt % of carbon black and have a thickness equal to about 13 μm.

### Example 2

A film is prepared like in Example 1 except that the used carbon black is the one sold by Degussa Company under the catalog designation No. SB5.

### Example 3

A film is prepared like in Example 1 except that the used carbon black is the one sold by Degussa Company under the catalog designation No. SB4.

### Example 4

A film is prepared like in Example 1 except that the mixture used for forming the film includes about 1 g of the carbon black slurry and about 220.9 g of the PAA solution. The obtained black polyimide film contains about 0.5 wt % of carbon black.

### Example 5

A film is prepared like in Example 1 except that the mixture used for forming the film includes about 4 g of the carbon black slurry and about 217.6 g of the PAA solution. The obtained black polyimide film contains about 2 wt % of carbon black.

### Example 6

A film is prepared like in Example 1 except that the mixture used for forming the film includes about 4 g of the carbon black slurry and about 69.6 g of the PAA solution. The obtained black polyimide film contains about 6 wt % of carbon black.

### Example 7

A film is prepared like in Example 1 except that the mixture used for forming the film includes about 4 g of the carbon black slurry and about 40 g of the PAA solution. The obtained black polyimide film contains about 10 wt % of carbon black.

### Example 8

A film is prepared like in Example 3 except that the mixture used for forming the film includes about 4 g of the carbon black slurry and about 40 g of the PAA solution. The obtained black polyimide film contains about 10 wt % of carbon black.

### Example 9

Preparation of the Matting Agent Slurry

About 100 g of SiO₂ and about 700 g of DMAC are mixed and agitated for 60 minutes. The mixture then is processed through a grinder to obtain a matting agent slurry.

Preparation of the Black Polyimide Film

A film is prepared like in Example 1 except that the mixture used for forming the film includes about 4 g of the carbon black slurry, about 2 g of the SiO₂ matting agent slurry and about 104.5 g of the PAA solution. The obtained black polyimide film contains about 4 wt % of carbon black and about 2 wt % of the matting agent.

### Example 10

A film is prepared like in Example 9 except that the mixture used for forming the film includes about 4 g of the carbon black slurry, about 5 g of the SiO₂ matting agent slurry and about 101.1 g of the PAA solution. The obtained black polyimide film contains about 4 wt % of carbon black and about 5 wt % of the matting agent.

### Example 11

A film is prepared like in Example 9 except that the mixture used for forming the film includes about 4 g of the carbon black slurry, about 10 g of the SiO₂ matting agent slurry and about 95.6 g of the PAA solution. The obtained black polyimide film contains about 4 wt % of carbon black and about 10 wt % of the matting agent.

### Example 12

Preparation of the Matting Agent Slurry

About 100 g of a polyimide powder and about 700 g of DMAC are mixed together and agitated for 60 minutes. The mixture is then processed through a grinder to obtain the matting agent slurry.

Preparation of the Black Polyimide Film

A film is prepared like in Example 1 except that the mixture used for forming the film includes about 4 g of the carbon black slurry, about 2 g of the matting agent slurry prepared from the polyimide powder, and about 104.5 g of the PAA solution. The obtained black polyimide film contains about 4 wt % of carbon black and about 2 wt % of the matting agent.

### Example 13

A film is prepared like in Example 12 except that the mixture used for forming the film includes about 4 g of the carbon black slurry, about 5 g of the matting agent slurry prepared from the polyimide powder, and about 101.1 g of the PAA solution. The obtained black polyimide film contains about 4 wt % of carbon black and about 5 wt % of the matting agent.

### Example 14

A film is prepared like in Example 12 except that the mixture used for forming the film includes about 4 g of the carbon black slurry, about 10 g of the matting agent slurry prepared from the polyimide powder, and about 95.6 g of the PAA solution. The obtained black polyimide film contains about 4 wt % of carbon black and about 10 wt % of the matting agent.

### Example 15

A film is prepared like in Example 14 except that the used carbon black is the one sold by Degussa Company under the catalog designation No. SB4.

### Comparative Example 1

A film is prepared like in Example 1 except that the used carbon black is the one sold by Cabot Company under the catalog designation No. M1000.

### Comparative Example 2

A film is prepared like in Example 1 except that the used carbon black is the one sold by Cabot Company under the catalog designation No. M1400.

### Comparative Example 3

A film is prepared like in Example 1 except that the used carbon black is the one sold by Cabot Company under the catalog designation No. R400R.

### Comparative Example 4

A film is prepared like in Example 1 except that the used carbon black is the one sold by Spring Green Company under the catalog designation No. ASEB.

### Comparative Example 5

A film is prepared like in Example 1 except that the used carbon black is the one sold by Cabot Company under the catalog designation No. LB101.

### Comparative Example 6

A film is prepared like in Comparative Example 1 except that the mixture used for forming the film includes about 8 g of the carbon black slurry and about 65.2 g of the PAA solution. The obtained black polyimide film contains about 12 wt % of carbon black.

### Comparative Example 7

A film is prepared like in Example 3 except that the mixture used for forming the film includes about 8 g of the carbon black slurry and about 65.2 g of the PAA solution. The obtained black polyimide film contains about 12 wt % of carbon black.

### Comparative Example 8

A film is prepared like in Comparative Example 1 except that the mixture used for forming the film includes about 1 g of the carbon black slurry and about 220.9 g of the PAA solution. The obtained black polyimide film contains about 0.5 wt % of carbon black.

### Comparative Example 9

A film is prepared like in Comparative Example 3 except that the mixture used for forming the film includes about 1 g of the carbon black slurry and about 220.9 g of the PAA solution. The obtained black polyimide film contains about 0.5 wt % of carbon black.

### Comparative Example 10

A film is prepared like in Comparative Example 4 except that the mixture used for forming the film includes about 1 g of the carbon black slurry and about 220.9 g of the PAA solution. The obtained black polyimide film contains about 0.5 wt % of carbon black.

### Comparative Example 11

A film is prepared like in Comparative Example 5 except that the mixture used for forming the film includes about 1 g of the carbon black slurry and about 220.9 g of the PAA solution. The obtained black polyimide film contains about 0.5 wt % of carbon black.

### Comparative Example 12

### Preparation of the Matting Agent Slurry

About 100 g of BaSO₄ and about 700 g of DMAC are mixed together and agitated for 60 minutes. The mixture is then processed through a grinder to obtain a matting agent slurry.

Preparation of the Black Polyimide Film

A film is prepared like in Example 1 except that the mixture used for forming the film includes about 4 g of the carbon black slurry, about 10 g of the BaSO₄ matting agent slurry and about 95.6 g of the PAA solution. The obtained black polyimide film contains about 4 wt % of carbon black and about 10 wt % of the matting agent.

### Comparative Example 13

### Preparation of the Matting Agent Slurry

About 100 g of Al₂O₃ and about 700 g of DMAC are together and agitated for 60 minutes. The mixture is then processed through a grinder to obtain a matting agent slurry.

Preparation of the Black Polyimide Film

A film is prepared like in Example 1 except that the mixture used for forming the film includes about 4 g of the carbon black slurry, about 10 g of the Al₂O₃ matting agent slurry and about 95.6 g of the PAA solution. The obtained black polyimide film contains about 4 wt % of carbon black and about 10 wt % of the matting agent.

The polyimide film prepared according to the aforementioned Examples and Comparative Examples are tested as follows.

Measure of the O/C weight ratio of carbon black: the polyimide film can be tested through an equipment including an electronic scanning microscope (Catalog No. JEOL6510) and an energy dispersive X-ray spectrometer (EDS) (Catalog No. OXFORD INCA x-act).

Volume resistivity: a resistance meter Agilent 4339B with 16008B Resistivity cell can be used for detecting the volume resistivity of the film.

Gloss: a glossmeter (Catalog No. Micro Tri Gloss—BYK Gardner) can be used to measure the 60° gloss value.

Mechanical elongation rate: the mechanical elongation rate can be measured according to the ASTM 882 standard test by using an universal tensile strength tester (Catalog No. Hounsfield H10ks).

Flaking test: the polyimide film is placed in a plasma etching desmear apparatus (Catalog No. NEMST-D2002). Plasma etching is applied by feeding O₂ at 2000 sccm, N₂ at 666 sccm and CF₄ at 333 sccm, and with energizing power set at 15 KW. The plasma etching treatment is conducted for about 30 minutes. Then, the polyimide film is retrieved, and is wiped twenty times with a white cleanroom wiper (having a surface area of about 19.6 cm²) impregnated with ethanol. The ability of the film to prevent flaking of carbon black is determined based on the observation of carbon black stain on the cleanroom wiper, which can be assessed according to the following method:

“Excellent”: the carbon black stain is less than 5% of the surface area of the cleanroom wiper;

“Good”: the carbon black stain is 5-10% of the surface area of the cleanroom wiper;

“Bad”: the carbon black stain is 11-30% of the surface area of the cleanroom wiper; and

“Worse”: the carbon black stain is larger than 30% of the surface area of the cleanroom wiper.

The test results are shown in Table 1.

TABLE 1

| | Carbon black | | | | | | |
|---|---|---|---|---|---|---|---|
| | O/C | | Matting | Volume | | Extension | Ability to |
| | weight | Content | agent | resistivity | Gloss | rate | prevent |
| | ratio (%) | (wt %) | (wt %) | (Ω-cm) | (GU) | (%) | flaking |
| Example | | | | | | | |
| 1 | 21.6 | 4 | 0 | >10¹⁵ | 97 | >40 | Excellent |
| 2 | 20.2 | 4 | 0 | >10¹⁵ | 101 | >40 | Good |
| 3 | 19.4 | 4 | 0 | >10¹⁵ | 98 | >40 | Good |
| 4 | 21.6 | 0.5 | 0 | >10¹⁵ | 106 | >40 | Excellent |
| 5 | 21.6 | 2 | 0 | >10¹⁵ | 103 | >40 | Excellent |
| 6 | 21.6 | 6 | 0 | >10¹⁵ | 95 | >40 | Excellent |
| 7 | 21.6 | 10 | 0 | >10¹⁵ | 93 | >40 | Excellent |
| 8 | 19.4 | 10 | 0 | >10¹⁵ | 94 | >40 | Good |
| 9 | 21.6 | 4 | 2 (SiO₂) | >10¹⁵ | 35 | >40 | Excellent |
| 10 | 21.6 | 4 | 5 (SiO₂) | >10¹⁵ | 24 | >40 | Excellent |
| 11 | 21.6 | 4 | 10 (SiO₂) | >10¹⁵ | 15 | >40 | Excellent |
| 12 | 21.6 | 4 | 2 (PI) | >10¹⁵ | 46 | >40 | Excellent |
| 13 | 21.6 | 4 | 5 (PI) | >10¹⁵ | 35 | >40 | Excellent |
| 14 | 21.6 | 4 | 10 (PI) | >10¹⁵ | 20 | >40 | Excellent |
| 15 | 19.4 | 4 | 10 (PI) | >10¹⁵ | 21 | >40 | Good |
| Comparative | | | | | | | |
| Example | | | | | | | |
| 1 | 11.0 | 4 | 0 | >10¹⁵ | 99 | >40 | Bad |
| 2 | 10.4 | 4 | 0 | >10¹⁵ | 96 | >40 | Bad |
| 3 | 6.6 | 4 | 0 | >10¹⁵ | 92 | >40 | Worse |
| 4 | 5.8 | 4 | 0 | >10¹⁵ | 97 | >40 | Worse |
| 5 | 2.1 | 4 | 0 | >10¹⁵ | 75 | >40 | Worse |
| 6 | 21.6 | 12 | 0 | Conductive | 86 | <40 | Good |
| 7 | 19.4 | 12 | 0 | Conductive | 81 | <40 | Bad |
| 8 | 11.0 | 0.5 | 0 | >10¹⁵ | 101 | >40 | Bad |
| 9 | 6.6 | 0.5 | 0 | >10¹⁵ | 106 | >40 | Worse |
| 10 | 5.8 | 0.5 | 0 | >10¹⁵ | 103 | >40 | Worse |
| 11 | 2.1 | 0.5 | 0 | >10¹⁵ | 94 | >40 | Worse |
| 12 | 21.6 | 4 | 10 (BaSO₄) | >10¹⁵ | 64 | <30 | Worse |
| 13 | 21.6 | 4 | 10 (Al₂O₃) | >10¹⁵ | 58 | <30 | Worse |

The test results show that the O/C weight ratio of the carbon black incorporated in the polyimide film can affect the color stability and the ability of the film to prevent flaking of carbon black.

Compared to those of Comparative Examples 1-5 and 8-11, the test results of Examples 1-15 show that black polyimide films containing carbon black having a O/C weight ratio higher than 11% do not exhibit decoloration. Moreover, flaking of the carbon black from the polyimide film is significantly reduced, even when the film is treated with plasma etching. In particular, the test results show that the higher O/C weight ratio of the carbon black, the better ability of the black polyimide film to prevent flaking of the carbon black. In contrast, significant flacking of the carbon black is observed for the polyimide films fabricated according to Comparative Examples 1-5 and 8-11.

The application of the black polyimide film, in particular when it used for making a flexible circuit board, may require specific insulation and mechanical characteristics. In order to meet these requirements, the carbon black is incorporated in the film in a preferable amount of about 0.5-10 wt % based on the total weight of the polyimide film. Referring to the test results obtained for Examples 1-15, the films containing carbon black of the adequate O/C weight ratio that is in the aforementioned 0.5-10 wt % range can effectively improve the flaking problem during etching and desmear process, and provide good insulation (volume resistivity higher than 10¹⁵Ω−cm) as well as desirable mechanical property (extension rate higher than 40%).

Referring to the test results obtained for Comparative Examples 6 and 7, it is further observed that in case the carbon black is incorporated in an amount that exceeds the aforementioned range of 0.5-10 wt %, the resulting film may exhibit undesirable flaking of the carbon black even when the O/C weight ratio of the carbon black is higher than 11%. Moreover, the films of Comparative Examples 6 and 7 exhibit electrical conductivity (i.e., over current) and undesirably low extension rates, which make them inadequate for use as insulating substrate inflexible circuit boards. Accordingly, the amount of the carbon black incorporated in the film also appears to be a factor for obtaining a film with the desirable characteristics.

In some embodiments of the black polyimide film, a matting agent can be added in order to reduce the gloss of the film. Referring to the test results obtained for Comparative Examples 12 and 13, it can be observed that the black polyimide films incorporating BaSO₄ and Al₂O₃ as matting agent exhibit serious flaking of the carbon black, and poor mechanical and optical characteristics (the extension rate is lower than 30% and the gloss higher than 50). In contrast, the test results obtained for Examples 9-15 show that when SiO₂ or polyimide powder is used as the matting agent, the black polyimide film can have a gloss lower than 50, exhibit desirable mechanical and insulation characteristics, and can effectively prevent flaking of the carbon black. Accordingly, SiO₂ or polyimide powder can be used as preferable matting agents for film applications that have these characteristic requirements. In one embodiment, based on the total weight of the polyimide film, the SiO₂ or polyimide powder matting agent can be incorporated in the film in an amount of about 2-10 wt %.

Advantages of the black polyimide films described herein include the ability to provide desirable low gloss, low transmittance and good insulation characteristics, and also prevent flaking of carbon black and decoloration of the film during plasma etching and desmear process. Accordingly, contamination of the equipment through which the film is processed (e.g., taping and electroplating equipment) can be prevented, which can reduce the maintenance cost of the equipment.

The foregoing realizations have been described in the context of particular embodiments. These embodiments are meant to be illustrative and not limiting. Many variations, modifications, additions, and improvements are possible. Accordingly, plural instances may be provided for components described herein as a single instance. Structures and functionality presented as discrete components in the exemplary configurations may be implemented as a combined structure or component. These and other variations, modifications, additions, and improvements may fall within the scope as defined in the claims that follow.

What is claimed is:

1. A black polyimide film comprising:
a polyimide polymer formed by reaction of diamine monomers with dianhydride monomers; and
a carbon black having an oxygen-to-carbon weight ratio higher than 11%.

2. The black polyimide film according to claim 1, wherein the carbon black is present in the polyimide polymer in an amount ranging from 0.5 wt % to 10 wt % based on the total weight of the polyimide film.

3. The black polyimide film according to claim 1, wherein the oxygen-to-carbon weight ratio is at least equal to or higher than 15%.

4. The black polyimide film according to claim 1, wherein the oxygen-to-carbon weight ratio is at least equal to or higher than 19%.

5. The black polyimide film according to claim 1, further including a matting agent.

6. The polyimide film according to claim 5, wherein the matting agent is a polyimide powder, silicon oxide, or a combination of the polyimide powder and silicon oxide.

7. A laminate comprising:
a black polyimide film according to claim 1; and
at least one metal layer disposed on a surface of the polyimide film.

8. A polyimide film comprising:
a polyimide polymer formed by reaction of diamine monomers with dianhydride monomers;
a carbon black having an oxygen-to-carbon weight ratio higher than 11%; and
a matting agent composed of polyimide particles, silicon oxide, or a combination of the polyimide particles and silicon oxide.

9. The polyimide film according to claim 8, wherein the carbon black is present in the polyimide polymer in an amount ranging from 0.5 wt % to 10 wt % based on the total weight of the polyimide film.

10. The polyimide film according to claim 8, wherein the oxygen-to-carbon weight ratio is at least equal to or higher than 15%.

11. The polyimide film according to claim 8, wherein the oxygen-to-carbon weight ratio is at least equal to or higher than 19%.

12. A laminate comprising:
the polyimide film according to claim 8; and
at least one metal layer disposed on a surface of the polyimide film.

13. A method of processing a black polyimide film, comprising:
providing a black polyimide film containing a polyimide polymer and a carbon black having an oxygen-to-carbon weight ratio higher than 11%; and
etching the black polyimide film, wherein the polyimide polymer and the carbon black are etched with a substantially same etching rate.

14. The method according to claim 13, wherein the carbon black is present in an amount ranging from 0.5 wt % to 10 wt % based on the total weight of the polyimide film.

15. The method according to claim 13, wherein the oxygen-to-carbon weight ratio is at least equal to or higher than 15%.

16. The method according to claim 13, wherein the oxygen-to-carbon weight ratio is at least equal to or higher than 19%.
